(19) United States
(12) Patent Application Publication
(10) Pub. No.: US 2025/0240915 A1
(43) Pub. Date: Jul. 24, 2025

(54) LIQUID COOLING SYSTEM FOR ELECTRONIC DEVICE

(71) Applicant: SHENZHEN ENVICOOL TECHNOLOGY CO., LTD., Shenzhen (CN)

(72) Inventors: Xiaoxin XU, Shenzhen (CN); Xiaolei AI, Shenzhen (CN); Zhen XIONG, Shenzhen (CN); Xiaojin CHENG, Shenzhen (CN)

(73) Assignee: SHENZHEN ENVICOOL TECHNOLOGY CO., LTD., Shenzhen (CN)

(21) Appl. No.: 18/805,888

(22) Filed: Aug. 15, 2024

(30) Foreign Application Priority Data
Jan. 19, 2024 (CN) 202410084738.4

(51) Int. Cl. H05K 7/20

(52) U.S. Cl. CPC H05K 7/20272; H05K 7/20763

(57) ABSTRACT

A liquid cooling system for an electronic device is provided. The liquid cooling system includes a liquid guide tube, a liquid cooling body, a multi-channel structure, and a liquid collection device. The liquid cooling body and the multi-channel structure are communicated through the liquid guide tube. The liquid collection device continuously surrounds the multi-channel structure, the liquid guide tube, and the liquid cooling body, and has a window to expose a heated surface of the liquid cooling body. In the liquid cooling system for an electronic device, the liquid guide tube, the liquid cooling body, and the multi-channel structure are continuously surrounded, which can effectively collect the leaking liquid in all areas, and sufficiently prolong the duration of continuous operation of the electronic device after the leakage of the liquid cooling system.

### CROSS REFERENCE TO RELATED APPLICATIONS

The present application claims priority to Chinese Patent Application No. 202410084738.4, titled “LIQUID COOLING SYSTEM FOR ELECTRONIC DEVICE”, filed on Jan. 19, 2024 with the China National Intellectual Property Administration, which is incorporated herein by reference in its entirety.

### FIELD OF THE INVENTION

The present application relates to the technical field of electronic devices, and in particular to a liquid cooling system for an electronic device.

### BACKGROUND

It is generally required for servers or even other electronic devices to dissipate heat from heating elements such as GPUs, CPUs, and switches. The current air cooling system is too large in size to be applied to some electronic devices. The current liquid cooling system is generally small in size, and occupies a small space, especially at the heating elements.

It is found upon the inventor's research that it is difficult for a liquid cooling system to avoid leakage in long-term use. If there is a leakage, especially, onto an electronic device, it will cause a huge loss.

In the process of making the present application, it is found by the inventors that a conventional liquid cooling system for an electronic device has the problem of liquid leakage.

### SUMMARY

In view of the above, the object of the present application is to provide a liquid cooling system for an electronic device that can effectively solve the problem of leakage in the liquid cooling system for the electronic device.

In order to achieve the above object, the present application provides the following technical solutions.

A liquid cooling system for an electronic device includes a liquid guide tube, a liquid cooling body, and a multi-channel structure. The liquid guide tube is communicated between the liquid cooling body and the multi-channel structure. The liquid cooling system further includes a liquid collection device. The liquid collection device continuously surrounds the multi-channel structure, the liquid guide tube, and the liquid cooling body, and has a window to expose a heated surface of the liquid cooling body.

In use of the liquid cooling system for an electronic device, the heated surface of the liquid cooling body abuts against the heating element of the electronic device. A cooling liquid is transported through the multi-channel structure and the liquid guide tube to the liquid cooling body to absorb heat and then is transported out of the liquid cooling body to take away the heat. If leakage occurs at any or a joint of the multi-channel structure, the liquid guide tube or the liquid cooling body, the leaking liquid can be collected by the liquid collection device in advance, so that leakage can be avoided to flow onto the electric device. In addition, the window is provided at the heated surface, so the heated surface can be exposed for heat absorption, and leakage generally does not occur at the heated surface due to the working requirements of the heated surface. Thus, the leakage can be avoided at all. In the liquid cooling system for an electronic device, the liquid guide tube, the liquid cooling body, and the multi-channel structure are continuously surrounded, so that the leaking liquid can be effectively collected in all areas, and the duration of continuous operation of the electronic device after the leakage of the liquid cooling system can be sufficiently prolonged. In addition, considering the working characteristics of the heated surface that the liquid basically does not leak at the heated surface, the window is provided at the heated surface, so that the heat exchange requirement can be met, and possible leakage points can be covered. In summary, the liquid cooling system for an electronic device can effectively solve the problem of low liquid leakage safety of the liquid cooling system for an electronic device.

In some embodiments, the liquid cooling system further includes a detector for detecting liquid leakage; and the detector is configured to obtain a leakage detection result before the liquid collection device is saturated with liquid.

In some embodiments, the liquid cooling system further includes a suction device; the liquid collection device is in a form of a protective shell, and a collection cavity is formed between the protective shell and at least one of the multi-channel structure, the liquid guide tube and the liquid cooling body. The suction device is configured to suck liquid from the collection cavity.

In some embodiments, the liquid cooling body includes a heated plate and a cover plate. A first sealing connection seam is formed between the cover plate and the heated plate to seal a liquid cooling cavity between the cover plate and the heated plate. The heated plate and an edge of the window are sealingly connected to form a second sealing connection seam surrounding the first sealing connection seam. A pocket between the first sealing connection seam and the second sealing connection seam is communicated with the collection cavity.

In some embodiments, the protective shell includes a first collection box arranged at the liquid cooling body, a protective outer tube sleeved on the liquid guide tube, and a second collection box arranged at the multi-channel structure. Two ends of the protective outer tube extend into the first collection box and the second collection box, respectively.

In some embodiments, the first collection box includes a trough body with an opening on its top and a first cover covering the opening of the trough body. The bottom of the trough body is provided with the window, and an edge of the heated plate is sealingly connected to the edge of the window. A gap is formed between an edge of the cover plate and an inner side wall of the trough body, so that liquid leaking from a sealing connection between the heated plate and the cover plate flows through the gap to a side of the cover plate away from the heated plate. A sheet detector for detecting whether there is leakage is laid on the cover plate.

In some embodiments, the second collection box includes a liquid receiving tray and a second cover covering on an upper side of the liquid receiving tray; and a side of the liquid receiving tray away from the liquid cooling body is inclined downward and is provided with a detector for detecting whether there is leakage.

In some embodiments, the second cover has a transparent portion for observing the multi-channel structure. Supporting legs are provided on both sides of the liquid receiving tray in an extension direction of the multi-channel structure, and both ends of the liquid receiving tray are obliquely mounted on the supporting legs located at the both ends, respectively.

In some embodiments, an end of the protective outer tube located in the first collection box is communicated with an inner cavity of the first collection box.

In some embodiments, the protective outer tube includes a transparent band wound into a tubular shape and a self-sealing strip connecting edges of two lateral sides of the transparent band along an extension direction of the transparent band; and a water leakage detection tape is attached to an inner side of the transparent band along the extension direction of the transparent band.

### BRIEF DESCRIPTION OF THE DRAWING

In order to more clearly illustrate the technical solutions in the embodiments of the present application or in the conventional technology, the following will briefly introduce drawings required in the description of the embodiments or the conventional technology. Apparently, the drawings in the following description are only some of the embodiments of the present application. For those skilled in the art, other drawings can also be obtained based on these drawings without creative efforts.

FIG. 1 is a schematic structural view of a server according to an embodiment of the present application;

FIG. 2 is a schematic structural view of a liquid cooling system for an electronic device according to an embodiment of the present application;

FIG. 3 is a schematic structural view of a first collection box according to an embodiment of the present application;

FIG. 4 is a schematic view of an internal structure of a first collection box according to an embodiment of the present application;

FIG. 5 is a schematic cross-sectional structural view of a first collection box according to an embodiment of the present application taken along the middle plane;

FIG. 6 is a schematic view showing an edge structure of a first collection box according to an embodiment of the present application;

FIG. 7 is a schematic structural view of a liquid cooling plate according to an embodiment of the present application;

FIG. 8 is a schematic structural view of a second collection box according to an embodiment of the present application; and

FIG. 9 is a schematic cross-sectional structural view of a second collection box according to an embodiment of the present application.

The reference signs in the figures are listed as follows:

liquid guide tube 1,
liquid cooling body 2,
multi-channel structure 3,
window 4,
second sealing connection seam 5,
first collection box 6,
second collection box 7,
protective outer tube 8,
sealing ring 9,
electronic element 10;
heated plate 2-1,
cover plate 2-2,
first sealing connection seam 2-3,
liquid cooling cavity 2-4;
trough body 6-1,
first cover 6-2,
gap 6-3;
liquid receiving tray 7-1,
second cover 7-2,
supporting leg 7-3.

### DETAIL DESCRIPTION OF EMBODIMENTS

A liquid cooling system for an electronic device is provided according to the embodiments of the present application, which can effectively solve the problem of leakage of the liquid cooling system for an electronic device.

The technical solutions in the embodiments of the present application are clearly and completely described below in conjunction with the drawings. Apparently, the described embodiments are only part of the embodiments of the present application, not all of the embodiments of the present application. Any other embodiment obtained by those skilled in the art based on the embodiments in the present application without creative efforts shall fall within the protection scope of the present application.

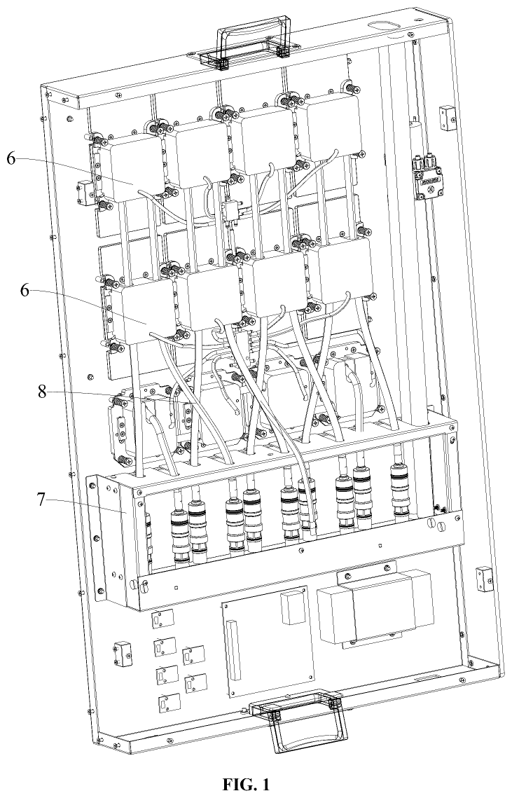

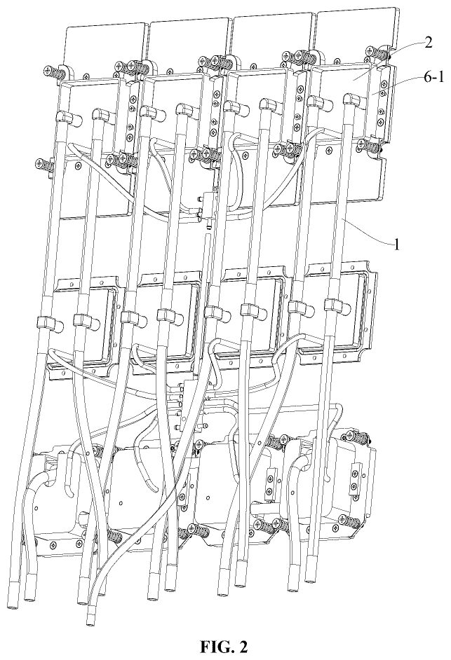

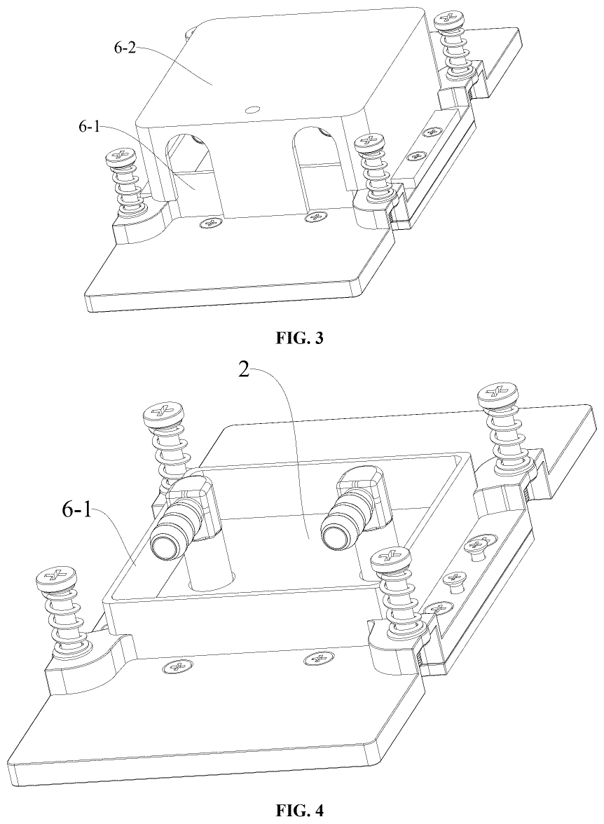

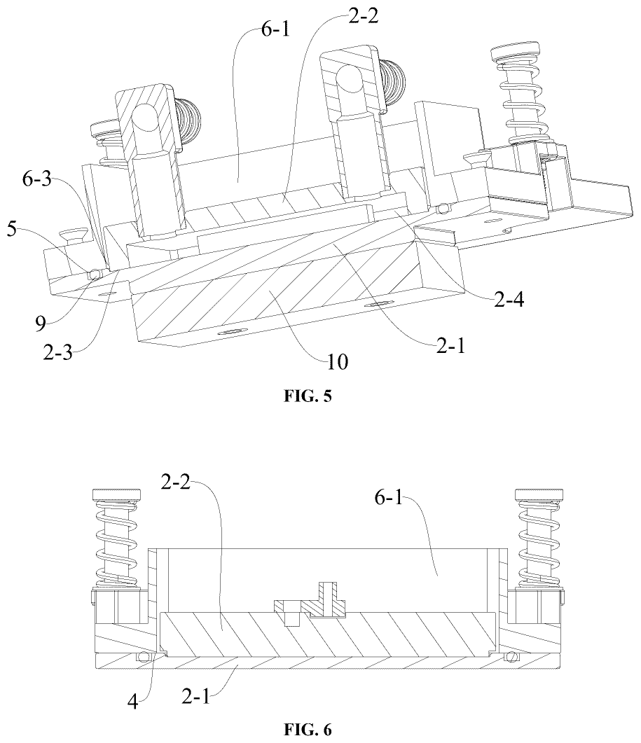

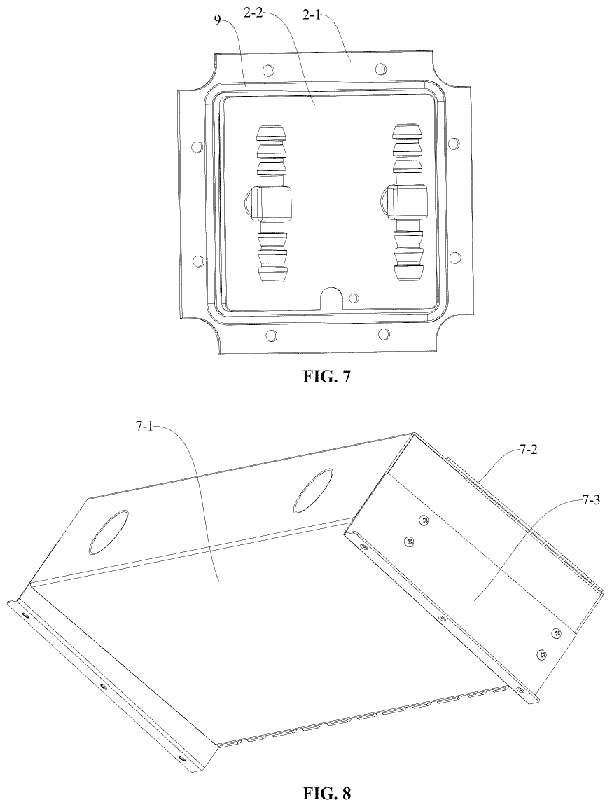

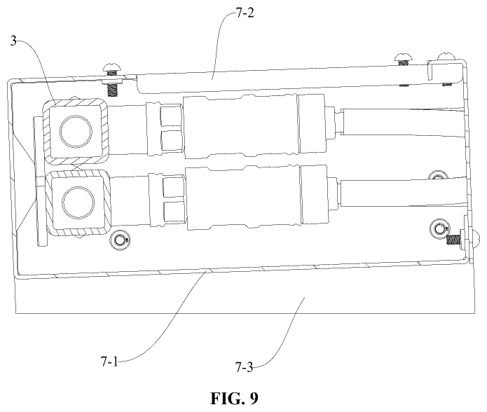

Referring to FIGS. 1-9, FIG. 1 is a schematic structural view of a server according to an embodiment of the present application; FIG. 2 is a schematic structural view of a liquid cooling system for an electronic device according to an embodiment of the present application; FIG. 3 is a schematic structural view of a first collection box according to an embodiment of the present application; FIG. 4 is a schematic view of an internal structure of a first collection box according to an embodiment of the present application; FIG. 5 is a schematic cross-sectional structural view of a first collection box according to an embodiment of the present application taken along the middle plane; FIG. 6 is a schematic view of an edge structure of a first collection box according to an embodiment of the present application; FIG. 7 is a schematic structural view of a liquid cooling plate according to an embodiment of the present application; FIG. 8 is a schematic structural view of a second collection box according to an embodiment of the present application; and FIG. 9 is a schematic cross-sectional structural view of a second collection box according to an embodiment of the present application.

In some embodiments, a liquid cooling system for an electronic device is provided to dissipate heat from an electronic element 10 of an electronic device. The electronic element 10 may be one or more of the following: GPU (Graphics Processing Unit), CPU (Central Processing Unit), switch (Switch), etc. The liquid cooling system for an electronic device mainly includes a liquid guide tube 1, a liquid cooling body 2, a multi-channel structure 3, and a liquid collection device.

The liquid cooling body 2 is generally a liquid cooling plate, but in some cases, may be of a block structure. At least one side surface of the liquid cooling body 2 is a heated surface, which is configured to abut against a heat dissipation surface of the electronic element 10 to be cooled. The heated surface of the liquid cooling body 2 is in thermal contact with the heat dissipation surface of the electronic element 10. In the case that the liquid cooling body 2 is a liquid cooling plate, one of the side surfaces of the plate may generally be the heated surface. Generally, a lower side surface of the liquid cooling plate is the heated surface for abutting against the upper side of the electronic element 10. A liquid cooling cavity 2-4 is formed inside the liquid cooling body 2, and the heat absorbed by the heated surface can be taken away by discharging liquid out of the liquid cooling cavity 2-4. In order to ensure the flow direction of the fluid inside the liquid cooling body 2, a curved flow channel may generally be formed inside the liquid cooling cavity 2-4 by a structure such as a partition.

The multi-channel structure 3 is configured to distribute water and/or to collect water, and generally may include a water distributor and/or a water collector. In some applications, the multi-channel structure 3 is also known as a water distribution-collection device, which is a generic term for a water distributor and a water collector, and may include one or both of the water distributor and the water collector. The multi-channel structure 3 may include a water distributor and a water collector. Generally speaking, a liquid feed header pipe for supplying liquid to the multi-channel structure 3 and a liquid return header pipe for returning liquid to the multi-channel structure 3 have high strength and are unlikely to leak, so they may not be completely surrounded by the liquid collection device. The liquid feed header pipe and the liquid return header pipe are communicated with a condenser so that the liquid returned from the liquid return header pipe can be cooled and then supplied to the multi-channel structure 3 through the liquid feed header pipe. In order to accelerate the flow of fluid, a booster pump may be provided.

The liquid cooling body 2 and the multi-channel structure 3 are directly or indirectly communicated through the liquid guide tube 1, so as to guide flow of liquid between the liquid cooling body 2 and the multi-channel structure 3. In a case that multiple liquid cooling bodies 2 are provided, there may be a liquid guide tube 1 which has one end connected to a liquid cooling body 2 and the other end communicated with the multi-channel structure 3 via another liquid cooling body 2. Furthermore, at least one liquid guide tube 1 may be used as a liquid supply pipe with one end connected to an outlet port of the water distributor in the multi-channel structure 3 and the other end connected to an inlet of the liquid cooling cavity 2-4 of the liquid cooling body 2. At least one liquid guide tube 1 is used as a liquid return pipe with one end connected to an inlet port of the water collector in the multi-channel structure 3 and the other end connected to an outlet of the liquid cooling cavity 2-4 of the liquid cooling body 2. In some cases, one or more of the liquid guide tubes 1 may be configured to both supply and return liquid, for example, in different time periods.

The liquid collection device continuously surrounds the multi-channel structure 3, the liquid guide tube 1, and the liquid cooling body 2. Since the multi-channel structure 3, the liquid guide tube 1, and the liquid cooling body 2 are surrounded and especially continuously surrounded by the liquid collection device, a joint of the multi-channel structure 3 and the liquid guide tube 1 and a joint of the liquid guide tube 1 and the liquid cooling body 2 are all surrounded by the liquid collection device. Thus, leaking liquid can be collected by the liquid collection device and does not fall directly onto the electronic element 10, so that the electronic device can continue to operate safely for a period of time after a leakage occurs. The liquid collection device is configured to constrain liquid in a specific location, including but not limited to at least one of the following: a liquid storage cavity formed on a shell or any other enclosure, in which the liquid is confined; a water absorbent body, e.g., water absorbent cotton, in which the liquid is confined.

Furthermore, the liquid collection device may have a window 4 formed to expose a heated surface of the liquid cooling body 2, so that the heated surface of the liquid cooling body can be in contact with the electronic element 10. The edge of the window 4 is in a sealed contact with the liquid cooling body 2, and preferably, is in a sealed contact with an one-piece structure of liquid cooling body 2 having the heated surface, so that a collection part of the liquid collection device can surround the joint between separate structures of the liquid cooling body 2 to collect the leaking liquid at this location. The term separate” in the separate structure and the term “one-piece” in the one-piece structure are relative concepts, and the separate elements may be connected by welding, bonding, a screw, etc. The size of the window 4 may be set according to the size of the exposed heated surface.

In some embodiments, when the liquid cooling system for an electronic device is used, the heated surface of the liquid cooling body 2 abuts against the heating element of the electronic device. A cooling liquid is transported through the multi-channel structure 3 and the liquid guide tube 1 to the liquid cooling body to absorb heat and then is transported out of the liquid cooling body to take away the heat. If leakage occurs at any or a joint of the multi-channel structure 3, the liquid guide tube 1 or the liquid cooling body 2, the leaking liquid can be collected by the liquid collection device in advance, so that leakage can be avoided to flow onto the electric device. In addition, the window 4 is provided at the heated surface, so the heated surface can be exposed for heat absorption, and leakage generally does not occur at the heated surface due to the working requirements of the heated surface. Thus, the leakage can be avoided at all. In the liquid cooling system for an electronic device, the liquid guide tube 1, the liquid cooling body 2, and the multi-channel structure 3 are continuously surrounded, so that the leaking liquid can be effectively collected in all locations, and the duration of continuous operation of the electronic device after the leakage of the liquid cooling system can be sufficiently prolonged. In addition, considering the working characteristics of the heated surface that the liquid basically does not leak at the heated surface, the window is provided at the heated surface, so that the heat exchange requirement can be met, and possible leakage points can be covered. In summary, the liquid cooling system for an electronic device can effectively solve the problem of low liquid leakage safety of the liquid cooling system for an electronic device.

In some embodiments, it is necessary to notify an operator that a leak has occurred before the liquid collection device is saturated with liquid. In this way, before the liquid collection device is saturated with liquid, the operator can perform as soon as possible some operations such as saving and/or backing up data, or stopping running of some program, which is necessary for imminent shutdown. The term “saturated” indicates that the liquid collection device cannot continue to collect the liquid, because a collection capacity of the liquid collection device is limited.

If the liquid collection device may be visually observed when collection liquid, it is possible to monitor by visual observation whether there is a leakage in the liquid cooling system. Thus, the leakage can be found before the liquid collection device is saturated with liquid. For example, the liquid collection device that collects liquid in a transparent bag can be visually observed as to whether there is a leak.

Regardless of whether the visual observation is possible, a detector may be provided to detect whether there is a leak. The detector is configured to obtain a leakage detection result before the liquid collection device is saturated. Obtaining the leakage detection result means that a leakage is detected. The leakage detection result is obtained before the liquid collection device is saturated with liquid, so that there is a time for the operator to perform corresponding operations. The detector may be a liquid detector to detect whether there is liquid. The liquid detector may be arranged in the liquid collection device. When liquid is detected in the liquid collection device, it indicates that there is a leak. The detector may also determine leakage by pressure changes of the liquid guide tube 1, the liquid cooling body 2, the multi-channel structure 3 or the like. The detector may determine leakage in such a manner as to be required actually.

Different detectors may be provided for the liquid guide tube 1, the liquid cooling body 2, and the multi-channel structure 3 to obtain detection results as soon as possible. After a leak occurs in the liquid cooling system, the longer the operator can operate the electronic device, the better. Therefore, it is desired to early detect whether a leakage occurs in the liquid cooling system, and/or to increase the collection capacity of the liquid collection device. The former may be achieved by positioning the detector as close as possible to a leak point, or the latter may be achieved by increasing volume of the liquid collection device.

In some embodiments, the liquid collection device may be formed as a protective shell. The protective shell continuously surrounds the liquid guide tube 1, the liquid cooling body 2, and the multi-channel structure 3. A collection cavity may be formed between the protective shell and at least one of the liquid guide tube 1, the liquid cooling body 2, and the multi-channel structure 3, so that in the event of leakage, whether it is spray leakage or seepage, the leaking liquid can be collected by the wall of the protective shell to be constrained in the collection cavity. The collection capacity corresponds to the size of the protective shell. It should be noted that the protective shell may be in an integrated shell structure, a split shell structure, or a structure assembled by multiple shell structures.

In some embodiments, a suction device may be provided. The suction device is configured to suck liquid out of the collection cavity, and the sucked liquid is separately stored or discharged from the server as waste liquid. The number and the distribution of suction ports of the suction device may be determined as needed. For example, the suction ports may be provided at the liquid cooling plates and the multi-channel structure 3, and the portion of the protective shell located at the liquid guide tube 1 may be communicated with the portion of the protective shell located at the liquid cooling plate to direct leaking liquid to the portion of the protective shell at the liquid cooling body and/or the portion of the protective shell at the multi-channel structure 3, thereby sucking liquid from the portion of the protective shell at the liquid cooling body and the portion of the protective shell at the multi-channel structure 3. The suction device may include a suction tube and a negative-pressure device. A multiple multi-way joint may be provided at the inlet of the negative-pressure device to form multiple suction ports which may extend into the portions of the protective shell at the liquid cooling plates and the portion of the protective shell at the multi-channel structure 3.

The volume of the collection cavity defined by the protective shell is limited, so liquid can be continuously sucked out of the liquid collection device by the suction device to avoid saturation of the collection cavity, thereby prolonging the time from obtaining the leakage detection result to the saturation of the liquid collection device.

In some embodiments, the liquid cooling body is formed with a liquid cooling cavity 2-4, and fins or other structures are provided in the liquid cooling cavity 2-4 to form a curved flow channel. The liquid cooling body may be integrally formed by 3D printing, but the cost is high. The liquid cooling body includes a heated plate 2-1 and a cover plate 2-2. The cover plate 2-2 and the heated plate 2-1 are sealingly connected to form a first sealing connection seam 2-3. The first sealing connection seam 2-3 seals the liquid cooling cavity 2-4 between the cover plate 2-2 and the heated plate 2-1. A liquid inlet and a liquid outlet of the liquid cooling cavity 2-4 may be formed in the cover plate 2-2. The sealing connection at the first sealing connection seam 2-3 may be realized by welding, or may be realized by a sealing ring, gluing, or the like. Since a high-pressure liquid is in the liquid cooling plate, there is a possibility that leakage may occur at the first sealing connection seam 2-3 between the cover plate 2-2 and the heated plate 2-1, that is, the possibility of cracking of the first sealing connection seam 2-3 is much greater than the possibility of cracking of the heated plate 2-1.

In some embodiments, the heated plate 2-1 and an edge of the window 4 are sealingly connected to form a second sealing connection seam 5 surrounding the first sealing connection seam 2-3. A pocket between the first sealing connection seam 2-3 and the second sealing connection seam 5 is communicated with the collection cavity. By arranging the second sealing connection seam 5, the liquid leaking from the first sealing connection seam 2-3 can be blocked the second sealing connection seam 5 to be retained in the collection cavity, effectively avoiding leakage from the window 4. It should be noted that the possibility of cracking of the first sealing connection seam 2-3 is much greater than the possibility of cracking of the second sealing connection seam 5, and the possibility of cracking of the second sealing connection seam 5 is very low, since the first sealing connection seam 2-3 is in working state for a long time and the liquid inside the liquid cooling cavity 2-4 is a high-pressure liquid, whereas the second sealing connection seam 5 is in working state only when leakage occurs and the pressure of the leaking liquid is much lower than the pressure of the fluid inside the liquid cooling cavity 2-4.

The sealing connection of the second sealing connection seam 5 may be realized by, but not limited to, welding, integrated molding, a sealing ring 9, gluing, or the like. The first sealing connection seam 2-3 and the second sealing connection seam 5 may be the same or different, and may be arranged as needed. In order to facilitate the installation of the protective shell, the sealing connection of the second sealing connection seam 5 may be realized by a sealing ring 9. For example, an annular groove may be formed on the heated plate 2-1 to receive the annular sealing ring 9, which abuts against the edge of the window 4, and then the heated plate 2-1 may be fixed to the window 4 by a screw or a bolt, with the sealing ring 9 being pressed, thereby ensuring the reliability of the seal.

As shown in the figures, the cover plate 2-2 is located inside the window 4, and a gap channel is formed between an edge of the cover plate 2-2 and a side wall of the window 4. The heated plate 2-1 is located outside the window 4, and has the edge extending outward beyond the edge of the cover plate 2-2 and abutting against and being in sealing contact with an outer side surface of the window 4, so as to form the second sealing connection seam 5. When a leak occurs, the fluid leaking from the first sealing connection seam 2-3 at the edge of the cover plate 2-2 flows laterally and, when flowing between the edge of the cover plate 2-2 and the side wall of the window 4, is blocked by the second sealing connection seam 5 formed at the edge of the window 4 and cannot flow out therefrom. Then, the fluid flows from the gap channel into the collection cavity of the protective shell.

In some embodiments, the protective shell described above may be a single structure. For example, the protective shell is in a large box structure, having a bottom provided with the window 4, and an upper or side portion provided with a through hole for a header pipe and/or for the suction tube. The liquid cooling body 2, the liquid guide tube 1, and the multi-channel structure 3 are located in the box structure. It should be noted that the liquid guide tube 1 and the multi-channel structure 3 may be completely surrounded by the box structure, that is, entirely located within a cavity of the box structure. The heated surface of the liquid cooling body 2 is exposed from the window 4 to abut against the electronic element 10 to be cooled, and the remaining part of the liquid cooling body 2 is located in the box structure. As shown in the figures, the heated plate 2-1 may be located on the outer side of the box structure, and is sealingly connected to the edge of the window 4 to prevent leakage. In a case that a suction device is provided, the suction ports may be provided at corners or the center of the box structure to uniformly suck the liquid. By providing a large box structure, the installation is convenient, and the protection is convenient with an improved protection effect. More cavities may be formed.

The unitary protective shell has both a large footprint and a large possibility of interference. As a result, it is easily affected by the actual scene, and may not be configured in a well harmonized way. In view of this, in some embodiments, the protective shell includes a first collection box 6 arranged at the liquid cooling body 2, a protective outer tube 8 provided outside of the liquid guide tube 1, and a second collection box 7 arranged at the multi-channel structure 3. In a case that multiple liquid cooling bodies 2 are provided, multiple first collection boxes 6 may be provided. The first collection box 6 may be provided with one or more windows 4 to place one or more liquid cooling bodies 2. Similarly, one or more liquid guide tubes 1 may be arranged in the protective outer tube 8. The first collection box 6 is provided with the window 4 for exposing the heated surface of the liquid cooling body 2. The water distribution-collection device may be completely surrounded by the second collection box 7. In some embodiments, one or each of the first collection box 6 and the second collection box 7 may adopt a collection bag.

In some embodiments, both ends of the protective outer tube 8 may extend into the first collection box 6 and the second collection box 7, which reduces the difficulties in arrangement between the protective outer tube 8 and the first collection box 6 as well as the arrangement between the protective outer tube 8 and the second collection box 7, and achieves sufficient protection. In order to prevent the liquid leaking out of the protective outer tube 8 from flowing outward along a tube wall of the protective outer tube 8, a baffle may be provided, or a seal retainer may be provided between the protective outer tube 8 and the corresponding through hole of the first collection box 6, and between the protective outer tube 8 and the corresponding through hole of the second collection box 7.

In some embodiments, a first collection box 6 is provided to collect leaking liquid at the liquid cooling plate. The first collection box 6 includes a trough body 6-1 with an opening on its top and a first cover 6-2 covering the opening of the trough body 6-1. The bottom of the trough body 6-1 is provided with a window 4, and the edge of the heated plate 2-1 is sealingly connected to the edge of the window 4, forming the second sealing connection seam 5 as described above. A gap 6-3 is formed between the edge of the cover plate 2-2 and an inner side wall of the trough body 6-1, so that the liquid leaking from the sealing connection between the heated plate 2-1 and the cover plate 2-2 can enter the side of the cover plate 2 away from the heated plate 2-1 through the gap 6-3. That is, the liquid leaking from the first sealing connection seam 2-3 does not flow out from the edge of the window 4 because the liquid is blocked by the second sealing connection seam 5, but flows into a portion, which is located on a side of the cover plate 2-2 away from the heated plate 2-1, of the cavity of the trough body 6-1 under the guidance of the gap 6-3. The portion, which is located on the side of the cover plate 2-2 away from the heated plate 2-1, of the cavity of the trough body 6-1 may serve as a collection cavity or as a part of the collection cavity.

In some embodiments, the side of the cover plate 2-2 away from the heated plate 2-1 is an upper side in actual application, and is provided with a liquid inlet and a liquid outlet that extend through the cover plate 2-2 to communicate with the liquid cooling cavity 2-4. The side of the cover plate 2-2 away from the heated plate 2-1 is provided with a joint for connecting the liquid guide tube 1, and the joint is located in the cavity of the trough body 6-1 and is covered by the first cover 6-2, so that the liquid leaking from the joint can be restrained in the cavity of the trough body 6-1.

In some embodiments, considering that the opening of the trough body 6-1 faces up in actual applications, the first cover and the trough body 6-1 may be sealingly connected, or the first cover 6-2 may simply cover the open top of the trough body 6-1. The first cover may have a wall located outside of the trough body 6-1, or may be inserted into the trough body 6-1 and in sealing contact with the inner side wall of the trough body 6-1.

An opening for receiving the liquid guide tube 1 may be arranged in the trough body 6-1 or may be arranged in the first cover 6-2. The opening may be arranged in the side wall of the first cover 6-2. For example, the side wall of the first cover 6-2 is provided with a groove. As such, the first cover 6-2 is covered on the trough body 6-1 after the liquid guide tube 1 is mounted, and the groove is matched with the liquid guide tube 1. The first cover 6-2 may be fixed to the trough body 6-1 by a screw.

In some embodiments, a trough body 6-1 of the first collection box 6 is provided as a mounting structure for the liquid cooling body 2. The liquid cooling body 2 is mounted on the trough body 6-1 through a connecting structure. A connecting plate extending transversely is provided on the outer side of the trough body 6-1, and the connecting plate is provided with a connecting part for connecting a housing of the electronic device to achieve fixation between the liquid cooling body 2 and the housing of the electronic device.

In some embodiments, the trough body 6-1 may be made of plastic to reduce the overall weight. Alternatively the trough body 6-1 may be made of metal or plastic with high thermal conductivity. The connecting plate provided on the trough body 6-1 may cover other low-heat-generating electronic elements to dissipate heat from the low-heat-generating electronic elements. After being transferred to the connecting plate, heat is transferred through other structures of the trough body 6-1 to the liquid cooling body 2, thereby realizing heat dissipation.

In some embodiments, in a case that a suction device is provided, a suction tube of the suction device may be inserted through the first cover 6-2 or the trough body 6-1 into the cavity of the trough body 6-1. In order to facilitate fixation and ensure the suction effect, a fixed connector may be provided and fixed to the cover plate 2-2. In order to achieve a better suction effect, a groove may be formed on the upper side of the cover plate 2-2 to better collect liquid and facilitate suction. Further, the fixed connector may include a transverse plate. One end of the transverse plate is located on the outer side of the groove and is mounted on the cover plate 2-2 through a screw, and the other end of the transverse plate is suspended from the groove. A side of the transverse plate facing the bottom of the groove has a protruding cylindrical portion, and the protruding cylindrical portion extends into the groove. A side of the transverse plate away from the groove is provided with a connecting column to match an opening of the suction tube. The connecting column has a hole passing through the transverse plate and the cylindrical portion to communicate with the bottom of the groove. The cylindrical portion extends into the groove with a reduced the gap between the cylindrical portion and a wall of the groove, ensuring a better suction effect.

In some embodiments, one first collection box 6 may correspond to one liquid cooling body 2. Thus, each liquid cooling body 2 may be mounted independently and fixed independently to the housing of the electronic device.

In some embodiments, for ease of installation, a sheet detector may be laid on the cover plate 2-2 to detect whether there is leakage.

In some embodiments, a second collection box 7 is provided to collect leaking liquid at the multi-channel structure 3. The liquid guide tube 1 also needs to be extended into the second collection box 7, so a joint between the liquid guide tube 1 and the multi-channel structure 3 needs to be located in the second collection box 7. Thus, the leaking liquid at the joint is also confined by the second collection box 7 in the cavity thereof.

The second collection box 7 may include a liquid receiving tray 7-1 and a second cover 7-2 covering on the upper side of the liquid receiving tray 7-1. The second cover 7-2 is configured to constrain liquid moving away from the liquid receiving tray 7-1 to the lower side of the second cover 7-2, so the liquid can be received by the liquid receiving tray 7-1. In the case that the suction device is provided, the suction device has at least one suction port which may be provided in the liquid receiving tray 7-1.

In some embodiments, considering that the volume of the water distribution and collection device in the form of a multi-channel structure 3 is significantly larger than that of the liquid cooling body 2, the volume of the second collection box 7 is also large accordingly. If the liquid receiving tray 7-1 is arranged horizontally, it is difficult to ensure the flatness of a tray surface of the liquid receiving tray 7-1, and it is difficult to quickly remove the liquid from the liquid receiving tray 7-1 due to liquid tension. In view of this, the tray surface of the liquid receiving tray 7-1 may be inclined, recessed, etc., to collect the liquid, and the suction port may be provided at a collection position.

For ease of manufacturing, the liquid receiving tray 7-1 may be obliquely arranged, so that the liquid on the liquid receiving tray 7-1 is collected at one position. In order to avoid the electronic element 10, the side of the liquid receiving tray 7-1 away from the liquid cooling body 2 may be inclined downward, so that the liquid on the liquid receiving tray 7-1 flows in a direction away from the liquid cooling body 2, and is collected on the corresponding side. In a case that a detector is provided to detect whether there is a liquid leakage, the detector may be located on the side of the liquid receiving tray 7-1 away from the liquid cooling body 2 to detect whether there is liquid at the collection position, thereby determining whether there is a leakage.

In some embodiments, the second cover 7-2 may be provided with a transparent portion for observing the multi-channel structure 3. The second cover 7-2 may be partially or entirely transparent to form the transparent portion. The amount of leaking liquid can be better observed through the transparent portion, so as to determine whether to perform emergency operation. The transparent portion may be made of glass or acrylic sheet.

In some embodiments, the inclined tray surface of the liquid receiving tray 7-1 may be achieved by gradually decreasing the thickness of the liquid receiving tray 7-1 towards one side, or by tilting the liquid receiving tray 7-1 as a whole.

In order to facilitate the inclined arrangement of the liquid receiving tray 7-1, a supporting leg 7-3 for inclined support may be provided on the lower side of the liquid receiving tray 7-1. For ease of installation, supporting legs 7-3 may be mounted on both sides of the liquid receiving tray 7-1, and are configured to connect the housing or the body of the electronic device. The liquid receiving tray 7-1 may be provided with the supporting legs 7-3 along an extension direction of the multi-channel structure 3. Both ends of the liquid receiving tray 7-1 may be obliquely mounted on the supporting legs 7-3 at both ends.

The supporting leg 7-3 may be formed of an L-shaped plate. A transverse plate portion of the L-shaped plate abuts against the inner side of the housing of the electronic device and may be connected to the housing of the electronic device by a screw. A vertical plate portion of the L-shaped plate is provided with multiple connection through holes arranged in a direction away from the liquid cooling body 2, and the distances between the multiple connection through holes and the transverse plate portion gradually decreases in the direction away from the liquid cooling body 2, so that the liquid receiving tray 7-1 is inclined downward. The L-shaped plates may be symmetrically arranged at two ends, so that the inclination degrees at the two ends are consistent.

In some embodiments, for ease of arrangement, the liquid receiving tray 7-1 may include a first plate body and two side plates respectively located at opposite ends of the first plate body. The first plate body includes a liquid receiving panel portion, a first vertical plate portion, and a second vertical plate portion that are integrally formed and connected. The first vertical plate portion is located on a side of the liquid receiving panel portion close to the liquid cooling body 2 and is integrally formed and connected to the liquid receiving panel portion. The second vertical plate portion is located on a side of the liquid receiving panel portion away from the liquid cooling body 2 and is integrally formed and connected to the liquid receiving panel portion. At both ends in the other direction, the two side plates are sealingly connected to the liquid receiving panel portion, the first vertical plate portion, and the second vertical plate portion, so that the first vertical plate portion, the second vertical plate portion and the two side plates enclose to form a groove wall structure to constrain the liquid on the liquid receiving panel portion. The outer side of the side plate is connected to the supporting leg 7-3, that is, is connected to the vertical plate portion of the supporting leg 7-3. The second cover includes an upper panel portion and a baffle portion that are integrally formed and connected to each other. The upper panel portion is located on the upper side of the liquid receiving panel portion, and the upper panel portion can cover the upper opening portion. In the vertical direction, the projection area of the liquid receiving panel portion may be larger than the projection area of the multi-channel structure 3 and the joints of the multi-channel structure 3. The baffle portion is connected to the side of the upper panel portion close to the liquid cooling body 2, and the baffle portion has a clamping groove to engage with the liquid guide tube 1 and the header pipe connected to the multi-channel structure 3. The upper panel portion may be provided with a transparent portion that is openable.

In some embodiments, the end of the protective outer tube 8 located inside the first collection box 6 may be communicated with the inner cavity of the first collection box 6, so that after the fluid in the protective outer tube 8 flows out from the end of the protective outer tube 8, the fluid enters the first collection box 6, so as to delay the saturation time of the protective outer tube 8. In the case that a suction device is provided, the above arrangement can facilitate the suction of the suction device.

In some embodiments, the protective outer tube 8 may be an integral tube to be directly sleeved on the liquid guide tube 1, which may result in inconvenient installation of a detection tape in the protective outer tube 8. In view of this, the protective outer tube 8 may include a transparent band which may be wound into a tubular shape and a self-sealing strip that connects edges of two lateral sides of the transparent band along the extension direction of the transparent band, so as to enable the transparent band in a tubular structure under the restraint of the self-sealing strip. The edges of two lateral sides of the transparent band may be connected in any other manner such as snap-fit or gluing, in addition to the self-sealing strip. It should be noted that since the leaking liquid is in a low-pressure state after entering the protective outer tube 8, the connection strength of the above connection manners is sufficient. It should be noted that the transparent band may be replaced with a non-transparent band, but the transparent band is easier to be observed. Correspondingly, the first cover 6-2 may be of a transparent structure or a partial transparent structure.

In the case that a detector is provided, a water leakage detection tape may be affixed to the inner side of the transparent band along the extension direction of the transparent band and serves as the detector described above. The water leakage detection tape may be arranged on the lower side of the liquid guide tube 1.

When the end of the protective outer tube 8 located in the first collection box 6 is required to be communicated with the inner cavity of the first collection box 6, the end of the protective outer tube 8 in the first collection box 6 can be loosely sleeved on the outer side of the liquid guide tube 1.

The embodiments in the specification are described in a progressive manner, and each embodiment focuses on the difference from other embodiments. Same and similar parts in each embodiment may be referred to each other.

The above description of the embodiments is provided to enable those skilled in the art to implement or use the present application. Various modifications to the embodiments are apparent to those skilled in the art. General principles defined herein may be implemented in other embodiments without departing from spirits or scopes of the present application. Therefore, the present application is not limited to the embodiments shown herein, but is to be accorded the widest scope consistent with the principles and novel features disclosed herein.

1. A liquid cooling system for an electronic device comprising a liquid guide tube, a liquid cooling body, a multi-channel structure and a liquid collection device, wherein
the liquid cooling body and the multi-channel structure are communicated through the liquid guide tube, and
the liquid collection device continuously surrounds the multi-channel structure, the liquid guide tube, and the liquid cooling body, and has a window to expose a heated surface of the liquid cooling body.

2. The liquid cooling system for an electronic device according to claim 1, further comprising a detector for detecting liquid leakage, wherein the detector is configured to obtain a leakage detection result before the liquid collection device is saturated with liquid.

3. The liquid cooling system for an electronic device according to claim 1, further comprising a suction device, wherein the liquid collection device is in a form of a protective shell, and a collection cavity is formed between the protective shell and at least one of the multi-channel structure, the liquid guide tube and the liquid cooling body; and the suction device is configured to suck liquid from the collection cavity.

4. The liquid cooling system for an electronic device according to claim 3, wherein the liquid cooling body comprises a heated plate and a cover plate; a first sealing connection seam is formed between the cover plate and the heated plate to seal a liquid cooling cavity defined by the cover plate and the heated plate, the heated plate and an edge of the window are sealingly connected to form a second sealing connection seam surrounding the first sealing connection seam, and a pocket between the first sealing connection seam and the second sealing connection seam is communicated with the collection cavity.

5. The liquid cooling system for an electronic device according to claim 4, wherein the protective shell comprises a first collection box arranged at the liquid cooling body, a protective outer tube sleeved on the liquid guide tube, and a second collection box arranged at the multi-channel structure; and two ends of the protective outer tube extend into the first collection box and the second collection box respectively.

6. The liquid cooling system for an electronic device according to claim 5, wherein the first collection box comprises a trough body having an opening on its top and a first cover covering the opening of the trough body, a bottom of the trough body is provided with the window, and an edge of the heated plate is sealingly connected to the edge of the window; a gap is formed between an edge of the cover plate and an inner side wall of the trough body, so that liquid leaking from a sealing connection between the heated plate and the cover plate flows through the gap to a side of the cover plate away from the heated plate; and a sheet detector is laid on the cover plate and configured to detect whether there is leakage.

7. The liquid cooling system for an electronic device according to claim 6, wherein the second collection box comprises a liquid receiving tray and a second cover covering on an upper side of the liquid receiving tray; and a side of the liquid receiving tray away from the liquid cooling body is inclined downward and is provided with a detector for detecting whether there is leakage.

8. The liquid cooling system for an electronic device according to claim 7, wherein the second cover has a transparent portion for observing the multi-channel structure; supporting legs are respectively provided on opposite sides of the liquid receiving tray in an extension direction of the multi-channel structure, and opposite ends of the liquid receiving tray are obliquely mounted on the supporting legs located at the ends, respectively.

9. The liquid cooling system for an electronic device according to claim 8, wherein an end of the protective outer tube located in the first collection box is communicated with an inner cavity of the first collection box.

10. The liquid cooling system for an electronic device according to claim 9, wherein the protective outer tube comprises a transparent band wound into a tubular shape and a self-sealing strip connecting edges of two lateral sides of the transparent band along an extension direction of the transparent band; and a water leakage detection tape is affixed to an inner side of the transparent band along the extension direction of the transparent band.
